(19) United States
(12) Patent Application Publication
(10) Pub. No.: US 2011/0298673 A1
(43) Pub. Date: Dec. 8, 2011

(54) FULL ANECHOIC CHAMBER FOR RADIATION EMISSION AND RADIATION SUSCEPTIBILITY TESTS

(75) Inventor: GANG ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/902,303

(22) Filed: Oct. 12, 2010

(30) Foreign Application Priority Data
Jun. 2, 2010 (CN) 201010188679.3

(51) Int. Cl. G01R 29/08

(52) U.S. Cl. 343/703

(57) ABSTRACT

A full anechoic chamber includes a first sidewall, a second sidewall substantially perpendicular to the first sidewall, a third sidewall opposite to the first sidewall, a fourth sidewall opposite to the second sidewall, a top wall substantially perpendicular to the first sidewall, and a bottom wall opposite to the top wall. The full anechoic chamber further includes an antenna holder system fixed on the bottom wall, an antenna detachably held by the antenna holder system and having a center axis thereof, and a loading table rotatably positioned on the bottom wall. The full anechoic chamber is symmetrical about a reference plane which extends along a direction substantially parallel to the second and fourth sidewalls and through the centers of the first and third sidewalls. The center axis of the antenna is arranged at an angle of about 8 degrees relative to the reference plane.

### BACKGROUND

1. Technical Field

The present disclosure relates to full anechoic chambers and, particularly, to a full anechoic chamber that can be used for carrying out both a radiation emission (RE) and a radiation susceptibility (RS) tests.

2. Description of Related Art

Generally, electrical products such as cell phones need to be tested for electro magnetic compatibility (EMC) in a full anechoic chamber under the standard number 22 of the International Special Committee on Radio Interference (CISPR22). The EMC tests typically includes an RE tests and an RS tests. However, a typical full anechoic chamber is usually designed for either RE tests or the RS tests. That is, a typical full anechoic chamber designed for the RE tests can't be used for the RS tests, and vice versa. Thus, there are required two full anechoic chambers respectively for the RE tests and RS tests, thereby increasing cost.

What is needed, therefore, is a full anechoic chamber which can ameliorate the above-described limitations.

### BRIEF DESCRIPTION OF THE DRAWINGS

FIG. 1 is a schematic, isometric view of a full anechoic chamber, according to an exemplary embodiment.

FIG. 2 is a schematic, isometric view of the full anechoic chamber of FIG. 1, viewed from another angle.

FIG. 3 is a cross-sectional view of the full anechoic chamber, taken along a line III-III of FIG. 1, showing an angle α.

FIG. 4 is a schematic, isometric view of a layer of a first radiation absorbing material.

FIG. 5 is a schematic, isometric view a layer of a second radiation absorbing material.

FIG. 6 is a schematic, isometric view of a layer of a third radiation absorbing material.

FIG. 7 is a schematic, isometric view of a layer of a fourth radiation absorbing material.

FIG. 8 is a graph showing a curve of a relationship between a site voltage standing wave ratio and the angle α.

### DETAILED DESCRIPTION

Embodiments of the present disclosure will be described next with reference to the accompanying drawings.

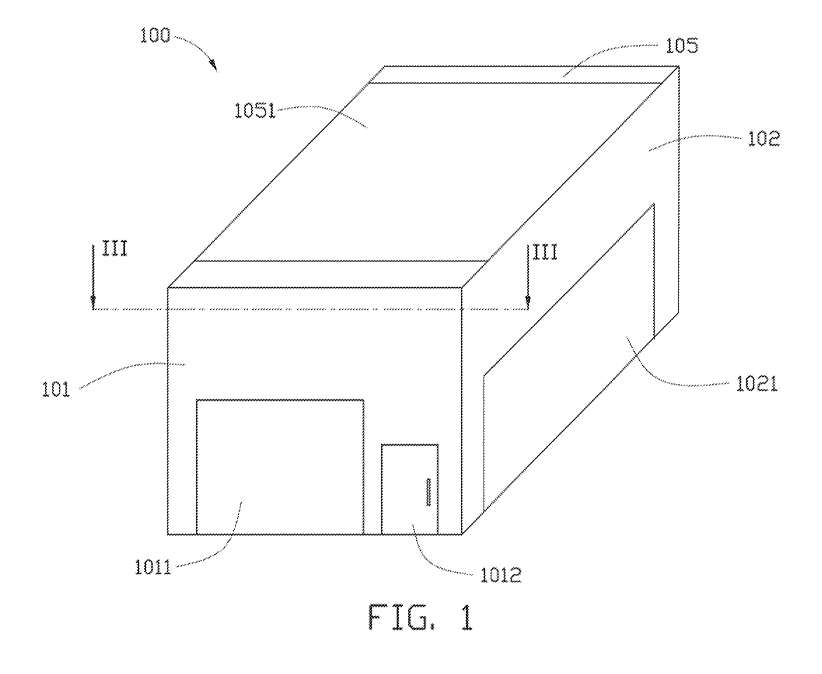

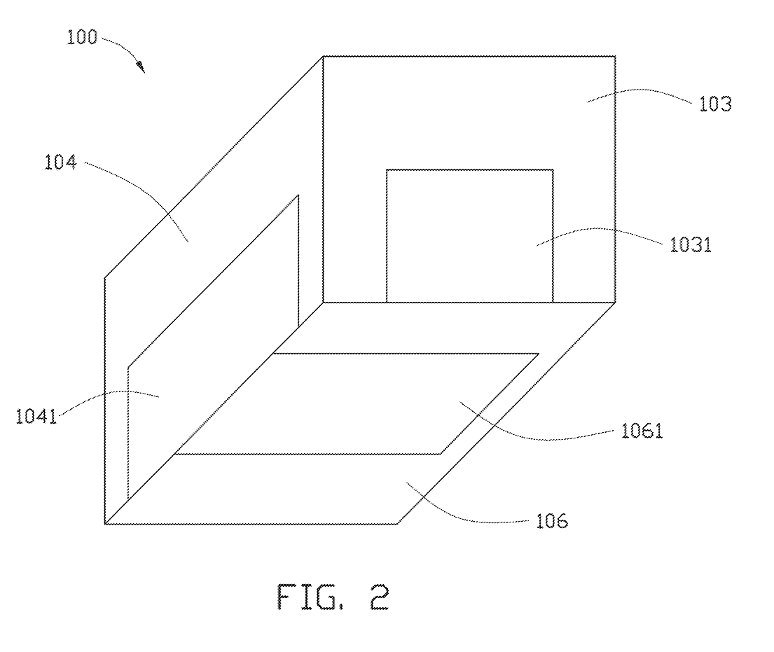

Referring to FIGS. 1-3, a full anechoic chamber 100, according to an exemplary embodiment, is configured for carrying out both RE tests and RS tests. In the present embodiment, the full anechoic chamber 100 can carry out the RE tests in which a working radio frequency is from about 1 GHz to about 6 GHz and the RS tests in which a working radio frequency is from about 80 MHz to about 3 GHz.

The full anechoic chamber 100 is generally a hollow cuboid chamber and includes a first sidewall 101, a second sidewall 102 substantially perpendicular to and connected to the first sidewall 101, a third sidewall 103 connected to the second sidewall 102 and opposite to the first sidewall 101, a fourth sidewall 104 connected to the first and third sidewalls 101, 103 and opposite to the second sidewall 102, a top wall 105 substantially perpendicular to the first sidewall 101 and the second sidewall 102, a bottom wall 106 opposite and parallel to the top wall 105, an antenna holder system 30, and a loading table 40. The antenna holder system 30 and the loading table 40 are oppositely positioned on the bottom wall 106. A reference plane AA extending along a direction substantially parallel to the second and fourth sidewalls 102, 104 and through the centers of the first sidewall 101 and the third sidewall 103 is defined. The reference plane AA is substantially perpendicular to the top and bottom walls 105, 106. The full anechoic chamber 100 is a symmetrical configuration about the reference plane AA. The full anechoic chamber 100 also includes a shielding door 1012 installed in the first sidewall 101.

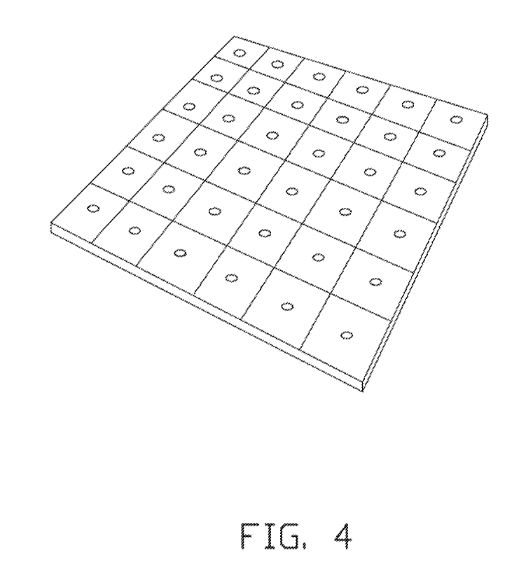

In order to effectively absorb radio wave, the inner surfaces of the first sidewall 101, the second sidewall 102, the third sidewall 103, the fourth sidewall 104, the top wall 105, and the bottom wall 106 are all covered with a layer of a first radiation absorbing material. In the present embodiment, the layer of the first radiation absorbing material includes an array of plates made of ferrite tiles of SN-20 made by the SAMWHA CAPACITOR GROUP as shown in FIG. 4.

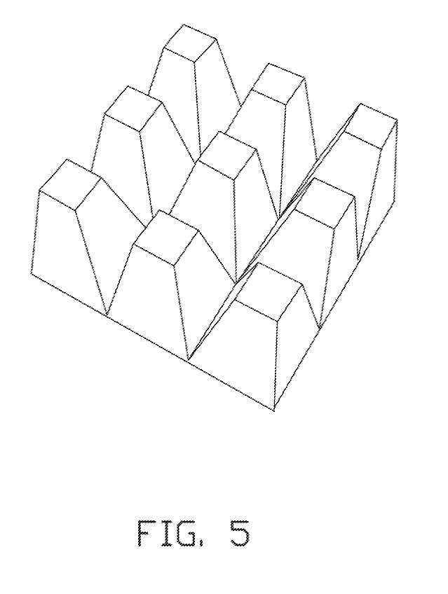

The first sidewall 101, the second sidewall 102, the third sidewall 103, the fourth sidewall 104, and the top wall 105 are partially covered with a layer of a second radiation absorbing material on the first radiation absorbing material and respectively formed five radio wave absorbing areas 1011, 1021, 1031, 1041 and 1051. In the present embodiment, the layer of the second radiation absorbing material includes an array of tapered rectangular columns made of carbon-loaded urethane foam of VHY-12-NRL made by EMERSON & CUMING MICROWAVE PRODUCTS N.V as shown in FIG. 5.

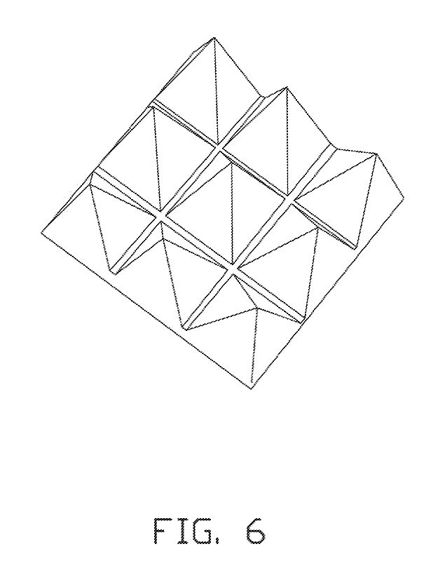

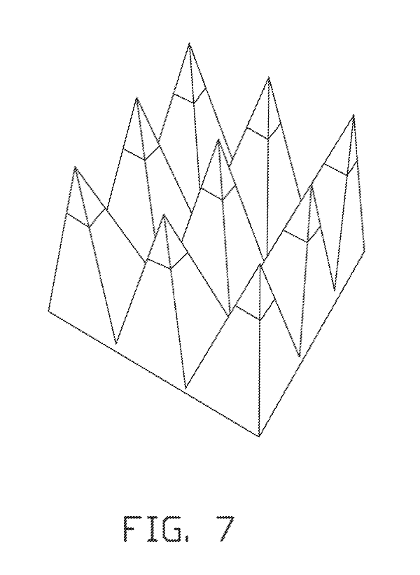

The bottom wall 106 forms a radio wave absorbing area 1061. Concretely, the radio wave absorbing area 1061 comprises a middle absorbing area 1062 and two side absorbing areas 1063 positioned at the two sides of the first absorbing area 1062. Each side absorbing area 1063 is covered with a layer of a third radio absorbing material. The middle absorbing area 1062 is covered with a layer of a fourth radiation absorbing material. In the present embodiment, the third radio absorbing material includes an array of pyramids made of carbon-loaded urethane foam of VHP-8-NRL made by EMERSON & CUMING MICROWAVE PRODUCTS N.V as shown in FIG. 6. The fourth radiation absorbing material includes an array of pyramids made of carbon-loaded urethane foam of VHP-18-NRL made by EMERSON & CUMING MICROWAVE PRODUCTS N.V as shown in FIG. 7. The following table 1 shows absorbing materials respect to the areas mentioned above.

TABLE 1

| | Absorbing | |
|---|---|---|
| | material | |
| Areas | type | Absorbing material |
| the fist sidewall to the fourth | the first | an array of plates made of |
| sidewall, the top wall, and the | radiation | ferrite tiles of SN-20 |
| bottom wall | absorbing | |
| | material | |
| the fist sidewall to the fourth | the second | an array of tapered rectangular |
| sidewall and the top wall | radiation | columns made of carbon- |
| | absorbing | loaded urethane foam of |
| | material | VHY-12-NRL |
| the two side absorbing areas | the third | an array of pyramids made of |
| | radiation | carbon-loaded urethane foam |
| | absorbing | of VHP-8-NRL |
| | material | |
| the middle absorbing area | the fourth | an array of pyramids made of |
| | radiation | carbon-loaded urethane foam |
| | absorbing | of VHP-18-NRL |
| | material | |

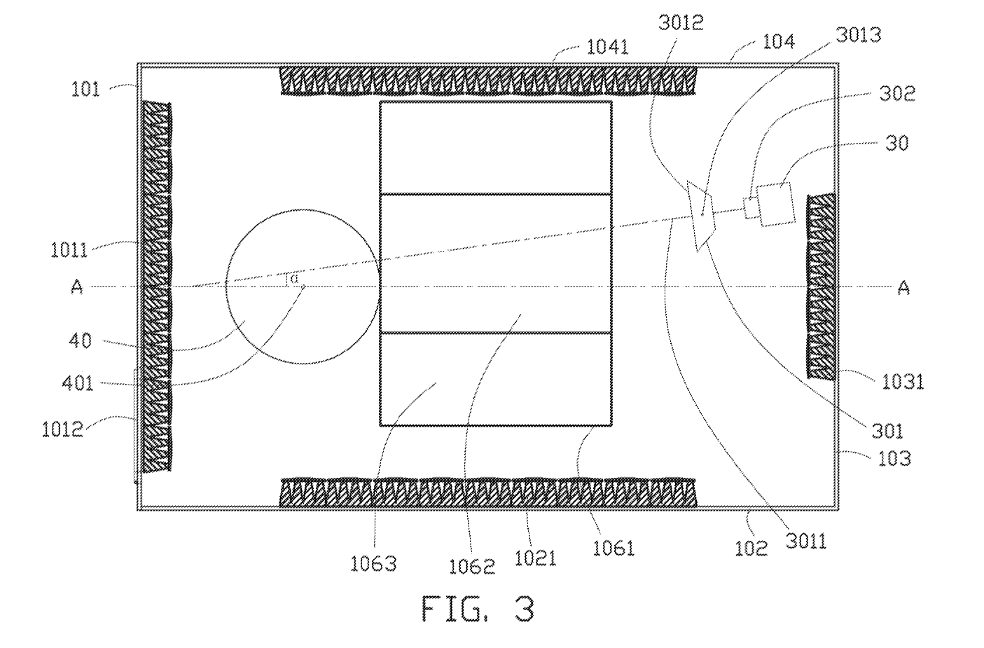

Referring to FIG. 3, the antenna holder system 30 and the loading table 40 are positioned at two sides of the radio wave absorbing area 1061. The antenna holder system 30 is positioned adjacent to the first sidewall 101. The loading table 40 is positioned adjacent to the third sidewall 103. The antenna holder system 30 can be movably positioned on the bottom wall 106 or fixed on the bottom wall 106. In the present embodiment, the antenna holder system 30 is fixed on the bottom wall 106.

An antenna 301 is detachably held by the antenna holder system 30. The antenna 301 has a symmetrical structure about a center axis 3011 thereof. The center axis 3011 of the antenna 301 is parallel to the bottom wall 106 and forms an acute angle α relative to the reference plane AA. The angle α is from about 5 degrees to about 10 degrees. In the present embodiment, the angle α is about 8 degrees.

The antenna 301 can be selected from a double-ridged waveguide horn antenna for the RE tests in which the radio frequency is from about 1 GHz to about 6 GHz, a microwave horn antenna for the RS tests in which the radio frequency is from about 1 GHz to about 3 GHz, and an ultra broadband antenna for the RS tests in which the radio frequency is from about 80 MHz to about 1 GHz, according to the type of tests to be carried out. In the present embodiment, each of the three types of antenna 301 respectively has a glass fiber tube 302 having a corresponding predetermined length. The glass fiber tube 302 is configured for conveniently mounting the antenna 301.

The loading table 40 is configured for loading an equipment under test (EUT) and has a pivot axis 401 positioned on the reference plane AA. When using the double-ridged waveguide horn antenna to carry out the RE tests, the EUT is loaded on the loading table 40, and the distance in a horizontal direction between the EUT and the center 3013 of the double-ridged waveguide horn antenna is about 3 meters, and the loading table 40 rotates about the pivot axis 401 and brings the EUT to rotate. When using the microwave horn antenna or the ultra broadband antenna to carry out the RS tests, the distance in a horizontal direction between the EUT and the front end 3012 of the microwave horn antenna or the ultra broadband antenna is about 3 meters, and the loading table 40 needn't to be rotated.

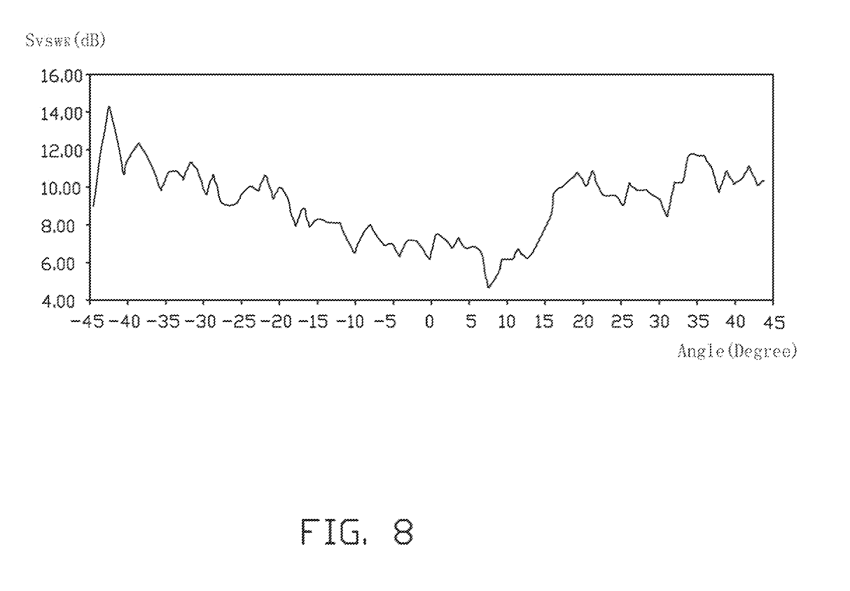

In order to satisfy the standard of the CISPR22, a site voltage standing wave ratio (S_{VSWR}) of the full anechoic chamber 100 must be lower than 6 dB. FIG. 8 shows a curve of the relationship between the S_{VSWR} and the angle α when the working radio frequency is about 6 GHz. The curve has a minimum point of about 4.58 dB when the angle α is about 8 degrees. Thus, the S_{VSWR} satisfies the standardization CISPR22. It is also proved that the S_{VSWR} also satisfies the standard of the CISPR22 in a working radio frequency range from about 1 GHz to about 6 GHz when the angle α is about 8 degrees. The full anechoic chamber 100 can be used in the RE tests in which the radio frequency is from about 1 GHz to about 6 GHz.

After setting the angle α as 8 degrees, the following tests for verifying whether or not the full anechoic chamber 100 satisfies the RS tests conditions are carried out. First, take a uniform field area (UFA) measurement in which the radio frequency is form about 1 GHz to about 3 GHz, the size of the UFA is 1.5 m×1.5 m. The following table 2 shows the result of the measurement.

TABLE 2

| | Result | | |
|---|---|---|---|
| | Unqualified | Unqualified frequency | Max absolute |
| Direction | frequency range | point number | difference |
| Horizontal | 1.9-2 GHz, | 9 | 9.4 dB |
| | 2.5-2.9 GHz | | |
| Vertical | 2.2 GHz, | 8 | 9.0 dB |
| | 2.4-2.8 GHz | | |

From the table 2, it is found that, the max absolute differences are 9.4 dB and 9.0 dB respectively in horizontal and vertical directions and both greater than a standard value of 6.0 dB defined in the standard of the CISPR22. The facts of the field identify is low in the four corner of the UFA and the beam width of the antenna is not enough cause the max absolute differences being greater than 6.0 dB. It is needed to decrease the area of the UFA.

Then take a UFA measurement in which the radio frequency is from about 1 GHz to about 3 GHz, the size of the UFA is 1 m×1 m. The following table 3 shows the result of the measurement.

TABLE 3

| | Result | | |
|---|---|---|---|
| | Unqualified | Unqualified frequency | Max absolute |
| Direction | frequency range | point number | difference |
| Horizontal | None | 0 | 5.8 dB |
| Vertical | None | 0 | 5.6 dB |

From the table 3, it is found that the max absolute differences are 5.8 dB and 5.6 dB respectively in horizontal and vertical directions and both smaller than 6.0 dB of the standardization CISPR22. Thus, it satisfies the standard CISPR22.

Then, take a UFA measurement in which the radio frequency is from about 80 MHz to about 1 GHz, the size of the UFA is 1.5 m×1.5 m. The following table 4 shows the result of the measurement.

TABLE 4

| | Result | | |
|---|---|---|---|
| | | Unqualified | |
| | Unqualified frequency | frequency point | Max absolute |
| Direction | range | number | difference |
| Horizontal | none | 0 | 4.8 dB |
| Vertical | none | 0 | 5.7 dB |

From the table 4, the max absolute differences are 4.8 dB and 5.7 dB respectively in horizontal and vertical directions and both smaller than 6.0 dB of the standardization CISPR22. Thus, it satisfies the standard CISPR22.

The full anechoic chamber 100 mentioned above can used for RE tests in which a working frequency is from about 1 GHz to about 6 GHz and RS tests in which a working frequency is from about 1 GHz to about 3 GHz.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A full anechoic chamber for RE tests and RS tests, comprising:
a first sidewall, a second sidewall substantially perpendicular to and connected to the first sidewall, a third sidewall opposite to the first sidewall, a fourth sidewall opposite to and parallel to the second sidewall, a top wall substantially perpendicular to the first sidewall and the second sidewall, and a bottom wall opposite to the top wall;
an antenna holder system positioned on the bottom wall;
an antenna detachably held by the antenna holder system and having a center axis; and
a loading table rotatably positioned on the bottom wall;
wherein the full anechoic chamber is symmetrical about a reference plane which extends along a direction substantially parallel to the second and fourth sidewalls and through the centers of the first sidewall and the third sidewall, and the center axis of the antenna is arranged at an angle of about 8 degrees with respect to the reference plane.

2. The full anechoic chamber of claim 1, wherein the antenna holder system is positioned adjacent to the third sidewall, the loading table is positioned on the bottom wall and adjacent to the first sidewall.

3. The full anechoic chamber of claim 1, wherein the inner surfaces of the first sidewall, the second sidewall, the third sidewall, the fourth sidewall, the top wall and the bottom wall are all covered with a layer of a first radiation absorbing material, the first radiation absorbing material comprises an array of plates.

4. The full anechoic chamber of claim 3, wherein the first sidewall, the second sidewall, the third sidewall, the fourth sidewall, and the top wall are partially covered with a second radiation absorbing material, the second radiation absorbing material comprises an array of tapered rectangular columns.

5. The full anechoic chamber of claim 4, wherein the bottom wall has a radio wave absorbing area, the radio wave absorbing area comprises a middle absorbing area and two side absorbing areas positioned at two sides of the middle absorbing area.

6. The full anechoic chamber of claim 5, wherein the two side absorbing areas are covered with a third radio absorbing material, the third radio absorbing material comprises an array of pyramids.

7. The full anechoic chamber of claim 5, wherein the middle absorbing area is covered with a fourth radio absorbing material, the fourth radiation absorbing material comprises an array of pyramids.

8. The full anechoic chamber of claim 1, wherein the antenna is selected from the group consisting of an double-ridged waveguide horn antenna, a microwave horn antenna and an ultra broadband antenna, the double-ridged waveguide horn antenna is configured for the RE tests in which a radio frequency from about 1 GHz to about 6 GHz is applied, the microwave horn antenna is configured for the RS tests in which a radio frequency from about 1 GHz to about 3 GHz is applied, the ultra broadband antenna is configured for the RS tests in which a radio frequency from about 80 MHz to about 1 GHz is applied,

9. The full anechoic chamber of claim 8, wherein the loading table is configured for loading an EUT, when using the double-ridged waveguide horn antenna to take the RE tests, the distance between the EUT and the center of the double-ridged waveguide horn antenna is about 3 meters

10. The full anechoic chamber of claim 8, wherein the loading table is configured for loading an EUT, when using the microwave horn antenna or the ultra broadband antenna to take the RS tests, the distance between the EUT and a front end of the microwave horn antenna or the ultra broadband antenna is about 3 meters.

11. The full anechoic chamber of claim 8, wherein each of the double-ridged waveguide horn antenna, the microwave horn antenna, and the ultra broadband antenna has a glass fiber tube.

12. The full anechoic chamber of claim 1, wherein the full anechoic chamber is a hollow cuboid chamber.

13. The full anechoic chamber of claim 1, wherein the loading table has a pivot axis, and the pivot axis is positioned on the reference plane.

14. A full anechoic chamber for RE tests and RS tests, comprising:
a bottom wall;
an antenna holder system positioned on the bottom wall;
an antenna detachably held by the antenna holder system and having a center axis; and
a loading table rotatably positioned on the bottom wall;
wherein the full anechoic chamber is symmetrical about a reference plane which is substantially perpendicular to the bottom wall, and the center axis of the antenna is arranged at an angle of about 8 degrees with respect to the reference plane.

15. The full anechoic chamber of claim 14, wherein the antenna holder system and the loading table are positioned at two opposite ends of the bottom wall.

16. The full anechoic chamber of claim 15, wherein the loading table has a pivot axis, and the pivot axis is positioned on the reference plane.

17. The full anechoic chamber of claim 14, wherein the full anechoic chamber is a hollow cuboid chamber.
